(19) United States
(12) Patent Application Publication
(10) Pub. No.: US 2007/0026642 A1
(43) Pub. Date: Feb. 1, 2007

(54) Surface modification method and surface modification apparatus for interlayer insulating film

(76) Inventor: Shingo Hishiya, Tokyo-To (JP)

Correspondence Address: SMITH, GAMBRELL & RUSSELL, 1850 M STREET, N.W., SUITE 800, WASHINGTON, DC, 20036, US

(21) Appl. No.: 10/554,086

(22) PCT Filed: Apr. 20, 2004
(86) PCT No.: PCT/JP04/05641

§ 371 Date: Oct. 21, 2005

(51) Int. Cl. H01L 21/20; C23C 16/00

(52) U.S. Cl. 438/478; 118/715; 118/725

(57) ABSTRACT

The present invention relates to a method for modifying a surface of an interlayer insulating film that is formed by applying a coating solution on a substrate to form a coating film, and sintering the coating film at a predetermined temperature. The method comprises the steps of: heating an inside of a reaction chamber that contains a substrate to a predetermined temperature; and modifying a surface of the interlayer insulating film by supplying an oxidizing gas into the reaction chamber.

### BACKGROUND OF THE INVENTION

1. Field of the Invention

The present invention relates to a method and apparatus for modifying a surface of an interlayer insulating film. More particularly, it pertains to a method and apparatus for modifying a surface of an interlayer insulating film of a low dielectric constant.

2. Background Art

In order to cope with the increased speed of an LSI, an interlayer insulating film is required to have a lower relative dielectric constant. There is a process therefor in which, for example, a substrate such as a semiconductor wafer is spin-coated with a coating solution formed of a low dielectric constant material, so as to form a coating film (SOD (Spin On Dielectrics) film) on the semiconductor wafer. The coating film is then sintered, so that an interlayer insulating film of a low dielectric constant can be obtained.

Along with a lower dielectric constant, in response to an LSI with a multilayer wiring structure or a miniaturized LSI, an interlayer insulating film is also required to have a satisfactory adhesiveness to a film deposited on an upper part of the interlayer insulating film, such as a CVD (Chemical Vapor Deposition) film called a hardmask, which is necessary for manufacturing a multilayer wiring structure. The interlayer insulating film formed by simply sintering a coating film may not sufficiently adhere to such a film. This is because the miniaturization of wiring lines may decrease a contact area between the two films, or may increase an aspect ratio thereof. In this case, the interlayer insulating film may be separated from the film deposited thereon, during a CMP (Chemical Mechanical Polishing) step, for example.

In order to solve this problem, it has been proposed that a surface of an interlayer insulating film is irradiated with plasma to modify the surface of the interlayer insulating film, so as to improve an adhesiveness of the interlayer insulating film to a film deposited thereon (see, for example, Japanese Patent Laid-Open Publication No. 78521/1996).

However, a plasma irradiation of a surface of an interlayer insulating film may degrade a film property of the interlayer insulating film. For example, it may cause an elevation in a dielectric constant of the interlayer insulating film, or may roughen the surface of the interlayer insulating film.

### SUMMARY OF THE INVENTION

The present invention has been made in view of the foregoing problems, and an object thereof is to provide a method and an apparatus for modifying a surface of an interlayer insulating film that is capable of improving an adhesiveness of the film, while preventing a deterioration of a property of the film.

Another object of the present invention is to provide a method and an apparatus for modifying a surface of an interlayer insulating film that is capable of improving an adhesiveness of the film, while maintaining a dielectric constant of the film.

The present invention is a method for modifying a surface of an interlayer insulating film that is formed by applying a coating solution on a substrate to form a coating film, and sintering the coating film at a predetermined temperature, the method comprising the steps of: heating an inside of a reaction chamber that contains a substrate to a predetermined temperature; and modifying a surface of the interlayer insulating film by supplying an oxidizing gas into the reaction chamber.

According to the present invention, since the surface of the interlayer insulating film formed on the substrate is modified by the oxidizing gas, an adhesiveness of the film can be improved, while a dielectric constant of the film is maintained. In addition, deterioration of a film property of the interlayer insulating film can be prevented.

Preferably, the oxidizing gas is any one of ozone, water vapor, oxygen, or a mixed gas of hydrogen and oxygen.

In addition, preferably, the predetermined temperature is in a range of from 250° C. to 600° C.; and the oxidizing gas is ozone.

Alternatively, preferably, the predetermined temperature is in a range of from 250° C. to 600° C.; and the oxidizing gas is a mixed gas of hydrogen and oxygen.

In addition, preferably, during the step of modifying a surface of the interlayer insulating film, the surface of the interlayer insulating film is modified such that a surface energy of the interlayer insulating film is at least 80 mN/m.

In addition, preferably, during the step of modifying a surface of the interlayer insulating film, the surface of the interlayer insulating film is modified such that a surface contact angle of water on the surface of the interlayer insulating film is less than 40°.

For example, the interlayer insulating film is an interlayer insulating film of a low dielectric constant. For example, the interlayer insulating film of a low dielectric constant is formed of a coating solution including polysiloxane having an organic functional group.

In addition, the present invention is an apparatus for modifying a surface of an interlayer insulating film that is formed by applying a coating solution on a substrate to form a coating film, and sintering the coating film at a predetermined temperature, the apparatus comprising: a reaction chamber that contains the substrate; a heating unit that heats an inside of the reaction chamber to a predetermined temperature; an oxidizing gas supplying unit that supplies an oxidizing gas into the reaction chamber; and a controller that controls the heating unit and the oxidizing gas supplying unit.

According to the present invention, since the surface of the interlayer insulating film formed on the substrate is modified by the oxidizing gas, an adhesiveness of the film can be improved, while a dielectric constant of the film is maintained. In addition, deterioration of a film property of the interlayer insulating film can be prevented.

Preferably, the oxidizing gas is any one of ozone, water vapor, oxygen, or a mixed gas of hydrogen and oxygen.

In addition, preferably, the predetermined temperature is in a range of from 250° C. to 600° C.; and the oxidizing gas is ozone.

Alternatively, preferably, the predetermined temperature is in a range of from 250° C. to 600° C.; and the oxidizing gas is a mixed gas of hydrogen and oxygen.

In addition, preferably, the controller controls the heating unit and the oxidizing gas supplying unit such that a surface energy of the interlayer insulating film is at least 80 mN/m.

In addition, preferably, the controller controls the heating unit and the oxidizing gas supplying unit such that a surface contact angle of water on the surface of the interlayer insulating film is less than 40°.

For example, the interlayer insulating film is an interlayer insulating film of a low dielectric constant. For example, the interlayer insulating film of a low dielectric constant is formed of a coating solution including polysiloxane having an organic functional group.

### BRIEF DESCRIPTION OF THE DRAWINGS

FIG. 1 is a view showing a film deposition apparatus in one embodiment according to the present invention;

FIG. 2A is a graph showing a relationship between contact angles of purified water relative to an interlayer insulating film and surface energies of the interlayer insulating film;

FIG. 2B is a graph showing a relationship between contact angles of purified water relative to an interlayer insulating film and polar component energies in a surface energy of the interlayer insulating film;

FIG. 3A is a table showing conditions for modifying a surface of an interlayer insulating film by means of ozone;

FIG. 3B is a graph showing contact angles of purified water relative to the interlayer insulating films whose surfaces have been modified in accordance with the conditions shown in FIG. 3A;

FIG. 4A is a table showing conditions for modifying a surface of an interlayer insulating film by means of water vapor;

FIG. 4B is a graph showing contact angles of purified water relative to the interlayer insulating films whose surfaces have been modified in accordance with the conditions shown in FIG. 4A;

FIG. 5A is a table showing conditions for modifying a surface of an interlayer insulating film by means of hydrogen and oxygen;

FIG. 5B is a graph showing contact angles of purified water relative to the interlayer insulating films whose surfaces have been modified in accordance with the conditions shown in FIG. 5A;

FIG. 6A is a table showing conditions for modifying a surface of an interlayer insulating film by means of oxygen;

FIG. 6B is a graph showing contact angles of purified water relative to the interlayer insulating films whose surfaces have been modified in accordance with the conditions shown in FIG. 6A;

FIG. 7A is a table showing conditions for modifying a surface of an interlayer insulating film by means of ultraviolet rays;

FIG. 7B is a graph showing contact angles of purified water relative to the interlayer insulating films whose surfaces have been modified in accordance with the conditions shown in FIG. 7A;

FIG. 8 is a graph showing a dielectric constant of the interlayer insulating film whose surface has been modified in accordance with the present invention, and a dielectric constant of an interlayer insulating film whose surface has not been modified; and

FIG. 9 is a view showing a heat treatment apparatus for modifying a surface of an interlayer insulating film by means of an ultraviolet irradiation.

### DETAILED DESCRIPTION OF THE INVENTION

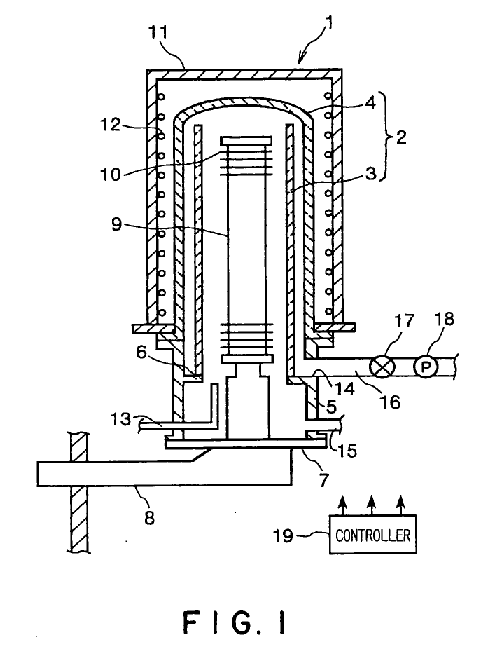

A method and an apparatus for modifying a surface of an interlayer insulating film in one preferred embodiment according to the present invention will be described hereinbelow, with reference to FIG. 1 showing a batch-type vertical heat treatment apparatus 1. FIG. 1 depicts a heat treatment apparatus for modifying a surface of an interlayer insulating film by means of an oxidizing gas.

As shown in FIG. 1, the heat treatment apparatus 1 is provided with a reaction tube 2 of substantially a cylindrical shape, which is arranged such that a longitudinal axis thereof is oriented in a vertical direction. The reaction tube 2 has a double tube structure including: an inner tube 3, and an outer tube 4 with a top wall that surrounds the inner tube 3 with a predetermined gap therebetween. The inner tube 3 and the outer tube 4 are formed of a heat-resistant material, such as quartz.

A cylindrical manifold 5 formed of stainless steel (SUS) is disposed under the outer tube 4. The manifold 5 is air-tightly connected to a lower end of the outer tube 4. The inner tube 3 is supported by a support ring 6, which is projected from an inner wall of the manifold 5.

A lid 7 is disposed below the manifold 5. The lid 7 is capable of being vertically moved by a boat elevator 8. When the lid 7 is lifted by the boat elevator 8, a lower side of the manifold 5 is closed by the lid 7.

A wafer boat 9 formed of, e.g., quartz is placed on the lid 7. The wafer boat 9 can contain a plurality of semiconductor wafers (substrates) 10 each having an interlayer insulating film of a low dielectric constant, which are arranged at predetermined vertical intervals. The interlayer insulating film formed on the semiconductor wafer 10 is, for example, a film formed of polysiloxane having an organic functional group. For example, the interlayer insulating film is formed on the semiconductor wafer 10 in line with the following steps. That is, the semiconductor wafer 10 is spin-coated with a coating solution including polysiloxane having an organic functional group to form a coating film, and then the coating film on the semiconductor wafer 10 is sintered, so that an interlayer insulating film is formed thereon.

A heat insulating member 11 is disposed around the reaction tube 2 to surround the same. A heater 12 for raising a temperature, such as a heating resistor, is disposed on an inner wall surface of the heat insulating member 11. An inside of the reaction tube 2 is heated by the heater 12 to a predetermined temperature, and hence the semiconductor wafers 10 can be heated to a predetermined temperature.

An oxidizing-gas introducing tube 13 that introduces an oxidizing gas pierces a side wall of the manifold 5. FIG. 1 shows only one oxidizing-gas introducing tube 13. The oxidizing-gas introducing tube 13 pierces the side wall of the manifold 5 below the support ring 6 so as to face an inside of the inner tube 3.

The oxidizing-gas introducing tube 13 is connected to a predetermined oxidizing-gas supply source, not shown, via a mass-flow controller or the like, not shown. The oxidizing gas is, for example, any one of ozone, water vapor, oxygen, or a mixed gas of hydrogen and oxygen. When the oxidizing gas is a mixed gas of hydrogen and oxygen, the mixed gas of hydrogen and oxygen is supplied from the common oxidizing-gas introducing tube 13. Alternatively, it is possible to separately supply hydrogen and oxygen from separate oxidizing-gas introducing tubes 13 so as to mix them in the reaction tube 2.

In an apparatus for modifying a surface of an interlayer insulating film by an ultraviolet irradiation, the oxidizing-gas introducing tube 13 is not needed, but an ultraviolet irradiation apparatus including a plurality of ultraviolet lamps is disposed on an inner wall surface of the heat insulating member 11, for example. In this apparatus, an interlayer insulating film on the semiconductor wafer 10 is irradiated with ultraviolet rays emitted from the ultraviolet lamps.

An exhaust port 14 is formed in the side wall of the manifold 5. The exhaust port 14 is located above the support ring 6, and is in communication with the space formed between the inner tube 3 and the outer tube 4 of the reaction tube 2. An exhaust gas generated in the inner tube 3 passes through the space between the inner tube 3 and the outer tube 4, and the exhaust gas is discharged to the exhaust port 14. A purge-gas supplying tube 15 for supplying a nitrogen gas as a purge gas pierces through the side wall of the manifold 5 below the exhaust port 14.

An exhaust tube 16 is hermetically connected to the exhaust port 14. A valve 17 and a vacuum pump 18 are disposed in the exhaust tube 16 in this order from an upstream side thereof. The valve 17 adjusts an opening degree of the exhaust tube 16 so as to control a pressure in the reaction tube 2 to a predetermined pressure. The vacuum pump 18 discharges the gas in the reaction tube 2 through the exhaust tube 16, and adjusts the pressure in the reaction tube 2.

A trap, a scrubber, and so on, not shown, are disposed in the exhaust tube 16. Thus, an exhaust gas discharged from the reaction tube 2 is detoxified in the exhaust tube 16, and thereafter the gas is emitted outside the heat treatment apparatus 1.

A controller 19 is connected to the boat elevator 8, the heater 12, the oxidizing-gas introducing tube 13, the purge-gas supplying tube 15, the valve 17, and the vacuum pump 18. The controller 19 consists of, e.g., a microprocessor or a process controller. The controller 19 measures temperatures and pressures and the like in respective parts of the heat treatment apparatus 1, and outputs control signals or the like to the respective parts based on the measured data, so as to control the respective parts of the heat treatment apparatus 1 in line with a predetermined recipe (time sequence).

Next, a method of modifying a surface of an interlayer insulating film is described hereinbelow. The method of modifying a surface of an interlayer insulating film includes the steps of: heating an inside of the reaction tube 2 that contains the semiconductor wafer 10 having the interlayer insulating film formed thereon to a predetermined temperature; and modifying a surface of the interlayer insulating film, by supplying an oxidizing gas into the reaction tube 2 (or by emitting ultraviolet rays onto the interlayer insulating film on the semiconductor wafer 10). A method for modifying a surface of an interlayer insulating film which is carried out by using the heat treatment apparatus 1 as stated above is explained below. In the below description, operations of the respective parts constituting the heat treatment apparatus 1 are controlled by the controller 19.

At first, the inside of the reaction tube 2 is heated by the heater 12 to a predetermined temperature. As described below, a suitable temperature range differs depending on a kind of an oxidizing gas to be used. The inside of the reaction tube 2 is heated to an optimum temperature corresponding to the kind of an oxidizing gas to be used.

Subsequently, the wafer boat 9 that contains the semiconductor wafer 10 on which the interlayer insulating film has been formed is placed on the lid 7. Then, the lid 7 is lifted by the boat elevator 8. Thus, the semiconductor wafer(s) 10 is loaded into the reaction chamber. If the coating film is sintered in the heat treatment apparatus 1 (a sintering operation of the coating film and a modifying operation of a surface thereof are consecutively performed in the same heat treatment apparatus 1), this loading step is unnecessary.

The interlayer insulating film is formed by, for example, spin-coating the substrate wafer 10 with a coating solution including polysiloxane having an organic functional group to form a coating film, and sintering the coating film on the semiconductor wafer 10. The coating solution including polysiloxane having an organic functional group is, for example, a solution formed by dissolving polysiloxane having an organic functional group in an organic solvent. The certain component such as a surface-active agent may be added to the solution. The interlayer insulating film formed according to the above method may be porous-methyl silsesquioxane (Porous-MSQ). Voids of a molecular or atomic size, e.g., voids of equal to or smaller than 20 nm may be formed in the interlayer insulating film.

Thereafter, the pressure in the reaction tube 2 is maintained at a predetermined pressure corresponding to the kind of an oxidizing gas to be used. Then, a predetermined amount of a predetermined oxidizing gas is supplied from the oxidizing-gas introducing tube 13 into the inner tube 3. With the supply of the oxidizing gas into the inner tube 3, a polar component energy in a surface energy of the interlayer insulating film is increased. As a result, the surface energy of the interlayer insulating film is increased. The reason for the increase in the polar component energy in the surface energy of the interlayer insulating film is considered that a part of the porous-MSQ (Si—CH₃) constituting the interlayer insulating film is substituted with a polar component such as (Si—CO), (Si—COH), (Si—O), and (Si—OH), by means of an oxidizing gas. A larger surface energy of the interlayer insulating film improves adhesiveness of the interlayer insulating film. That is, the interlayer insulating film can more tightly adhere to a film formed thereon, e.g., a hardmask.

Alternatively, when a surface of the interlayer insulating film is modified by an ultraviolet irradiation, ultraviolet rays are emitted from the ultraviolet lamps (not shown) disposed in the heat treatment apparatus 1 onto the interlayer insulating film on the semiconductor wafer 10. A surface energy of the interlayer insulating film is increased by this ultraviolet irradiation.

After the surface of the interlayer insulating film is modified, the vacuum pump 18 is operated to discharge the gas in the reaction tube 2 to the exhaust tube 16, while an opening degree of the valve 17 is controlled. The pressure in the reaction tube 2 is returned to a normal pressure, and the lid 7 is lowered by the boat elevator 8, so that the semiconductor wafer(s) 10 is unloaded.

Next, in order to check an effect of the embodiment, semiconductor wafers 10, on each of which the interlayer insulating film of porous-MSQ had been formed, were contained in the heat treatment apparatus 1 (reaction tube 2) heated at a predetermined temperature. Following thereto, a modification of a surface of the interlayer insulating film by means of ozone, a modification of a surface of the interlayer insulating film by means of water vapor, a modification of a surface of the interlayer insulating film by means of oxygen, and a modification of a surface of the interlayer insulating film by means of hydrogen and oxygen were carried out, by supplying ozone, water vapor, oxygen, and hydrogen and oxygen as an oxidizing gas. In addition, semiconductor wafers 10 similar to the above were irradiated with ultraviolet rays, so as to modify a surface of the interlayer insulating film. Thereafter, adhesiveness and a surface energy of each of the interlayer insulating films were measured.

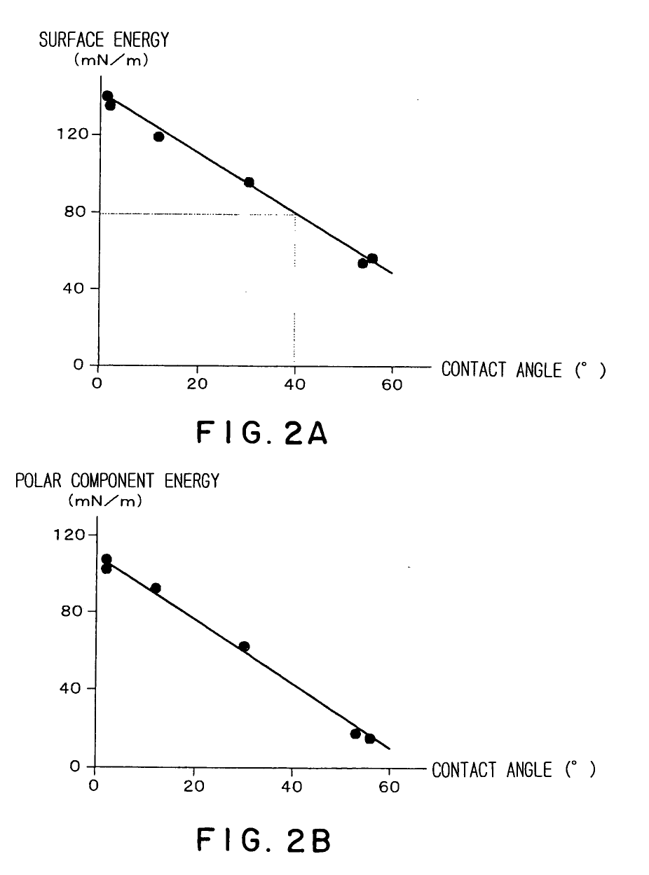

A surface energy of the modified interlayer insulating film was measured by a contact angle method. In the contact angle method, a liquid is dropped on an interlayer insulating film, and a contact angle formed between a droplet of the liquid and a surface of the interlayer insulating film is measured. FIG. 2A shows a relationship between contact angles of purified water relative to an interlayer insulating film and surface energies of the interlayer insulating film. FIG. 2B shows a relationship between contact angles of purified water relative to an interlayer insulating film and polar component energies in a surface energy of the interlayer insulating film.

A surface energy of the interlayer insulating film was calculated, with reference to a calculation method of a solid surface free energy (surface energy) based on the Owens-Wendt theories. In this method, liquids of different surface tensions are used, and contact angles of the respective liquids relative to an interlayer insulating film are measured. Then, a variance component, a polar component, and a hydrogen bond component are calculated based on an equation of Dupre-Young. Then, a surface energy (surface tension) is derived from the variance component, the polar component, and the hydrogen bond component, based on an extended equation of Fowkes. In these experiments, purified water, ethyleneglycol, and diiodomethane were employed as the liquids of different surface tensions.

In view of FIG. 2A showing a correlation between a contact angle of purified water relative to the interlayer insulating film and a surface energy thereof, the larger the surface energy becomes, the smaller the contact angle of purified water relative to the interlayer insulating film becomes. In view of FIG. 2B showing a correlation between a contact angle of purified water relative to the interlayer insulating film and a polar component energy in a surface energy of the interlayer insulating film, the larger the polar component energy becomes, the smaller the contact angle of purified water relative to the interlayer insulating film becomes. The correlation shown in FIG. 2B leads the correlation shown in FIG. 2A. Further, a hardmask was formed on the interlayer insulating film, and a CMP (Chemical Mechanical Polishing) test was conducted to obtain a surface energy value of the interlayer insulating film which makes it difficult for the interlayer insulating film to be peeled off from the hardmask. As a result, it was found that a surface energy of equal to or more than 80 mN/m is preferable, and that a surface energy of equal to or more than 100 mN/m is more preferable. Accordingly, in order to improve adhesiveness of an interlayer insulating film, that is, adhesiveness of an interlayer insulating film to a film formed thereon, such as a hardmask, a surface of the interlayer insulating film is modified such that a contact angle of purified water relative to the interlayer insulating film is preferably equal to or less than 40°, more preferably equal to or less than 20°.

Hereinbelow, the modification of a surface of an interlayer insulating film by means of ozone, the modification of a surface of an interlayer insulating film by means of water vapor, the modification of a surface of an interlayer insulating film by means of hydrogen and oxygen, the modification of a surface of an interlayer insulating film by means of oxygen, and the modification of a surface of an interlayer insulating film by means of ultraviolet rays are illustrated in this order.

(Modification of Surface of Interlayer Insulating Film by means of Ozone)

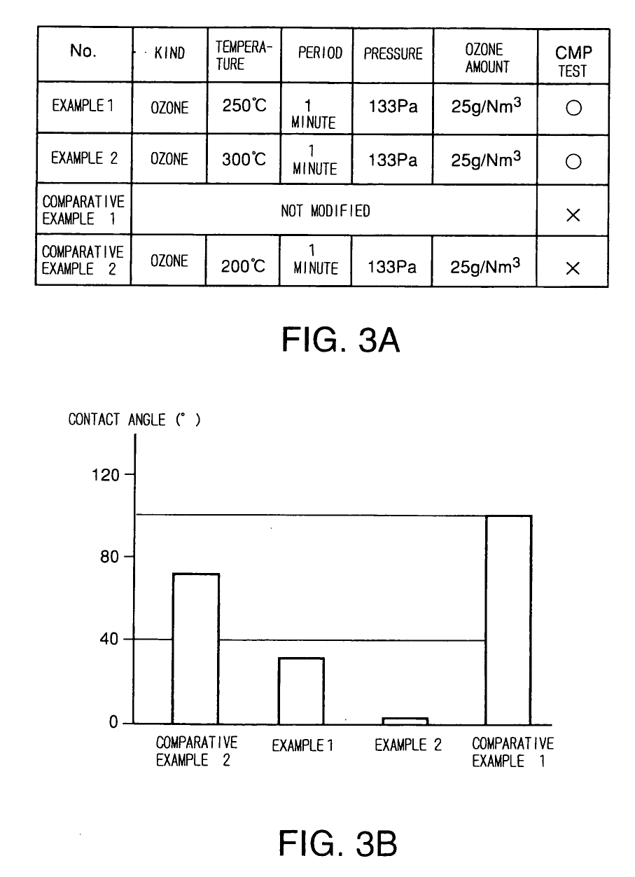

In Examples 1 and 2 and Comparative Example 2, a surface of an interlayer insulating film was modified by ozone, under conditions that a period of supplying ozone from the oxidizing-gas introducing tube 13 was one minute, a pressure in the reaction tube 2 was 133 Pa (1 Torr), an amount of ozone was 25 g/Nm³, while a temperature in the reaction tube 2 was set at 200° C. (Comparative Example 2), 250° C. (Example 1), and 300° C. (Example 2). Then, a contact angle of purified water relative to the interlayer insulating film was measured for each of the interlayer insulating films. FIG. 3A shows conditions for modifying a surface of the interlayer insulating film by means of ozone. FIG. 3B shows contact angles of purified water relative to the interlayer insulating films whose surfaces have been modified. After the surface of each of the interlayer insulating films was modified, a hardmask was formed thereon and the CMP test was conducted. FIG. 3A shows the results (wherein an interlayer insulating film tightly adhered to the hardmask and not peeled off therefrom is represented by a mark ◯, while an interlayer insulating film not tightly adhered to the hardmask and peeled off therefrom is represented by a mark ×). In addition, as to an interlayer insulating film whose surface has not been modified (Comparative Example 1), a contact angle of purified water relative to the interlayer insulating film was measured, and the CMP test was conducted. The results are also shown in FIGS. 3A and 3B.

As shown in FIGS. 3A and 3B, in the case wherein the temperature in the reaction tube 2 was equal to or more than 250°(Example 1), the contact angle of purified water relative to the interlayer insulating film was equal to or less than 40°, and a satisfactory result of the CMP test was also obtained. In the case wherein the temperature in the reaction tube 2 was 300° C. (Example 2), the contact angle of purified water relative to the interlayer insulating film was as small as equal to or less than 20°, and a satisfactory result of the CMP test was also obtained. That is, it was confirmed that a modification of a surface of an interlayer insulating film by means of ozone can improve adhesiveness of the interlayer insulating film, so that the interlayer insulating film can more tightly adhere to a hardmask.

On the other hand, in the case wherein the temperature in the reaction tube 2 was 200° C. (Comparative Example 2), the contact angle of purified water relative to the interlayer insulating film was more than 40°, and the result of the CMP test was unacceptable. The reason therefor is considered that the lower temperature in the reaction tube 2 inhibited a sufficient activation of ozone supplied into the reaction tube 2, when the ozone reacted with the interlayer insulating film to be modified, so that a part of the porous-MSQ constituting the interlayer insulating film could not be sufficiently substituted with a polar component. However, even when the temperature in the reaction tube 2 is 200° C., a satisfactory surface modification (increase in a surface energy) can be certainly achieved, provided that the conditions for modifying a surface of the interlayer insulating film by means of ozone are changed (for example, an ozone concentration of equal to or more than 25 g/Nm³, or a treatment period of equal to or more than one minute).

Herein, a heat treatment at a high temperature is not preferred in a device using the porous-MSQ. Thus, the temperature in the reaction tube 2 is preferably equal to or less than 600° C., more preferably equal to or less than 400° C. Therefore, a temperature in the reaction tube 2 when a surface of an interlayer insulating film is modified by ozone is preferably equal to or less than 600° C., more preferably in a range of from 200° C. to 400° C.

A pressure in the reaction tube 2 when a surface of an interlayer insulating film is modified by ozone is preferably in a range of from 0.3 Pa (0.003 Torr) to 101 kPa (normal pressure), more preferably in a range of from 0.3 Pa (0.003 Torr) to 6.65 kPa (50 Torr). This is because a minimum pressure of the heat treatment apparatus 1 is about 0.3 Pa, and the ozone tends to be deactivated when the pressure is increased. The higher the treatment temperature is, the more clearly the ozone develops the above tendency. For example, when a temperature in the reaction tube 2 is 300° C., a pressure therein is preferably equal to or less than 6.65 kPa (50 Torr), in order that a surface of an interlayer insulating film can be sufficiently oxidized by the ozone.

In the modification of a surface of an interlayer insulating film by means of ozone, an ozone supplying period is preferably equal to or less than 60 minutes, more preferably equal to or less than 30 minutes, most preferably equal to or less than 10 minutes. A sintering period for a film of a device using the porous-MSQ is generally in a range of from 30 minutes to 60 minutes. The above values are determined taking into consideration an actual productivity. In the modification of a surface of an interlayer insulating film by means of ozone, an amount of ozone is preferably equal to or less than 200 g/Nm³, more preferably equal to or less than 100 g/Nm³.

(Modification of Surface of Interlayer Insulating Film by means of Water Vapor)

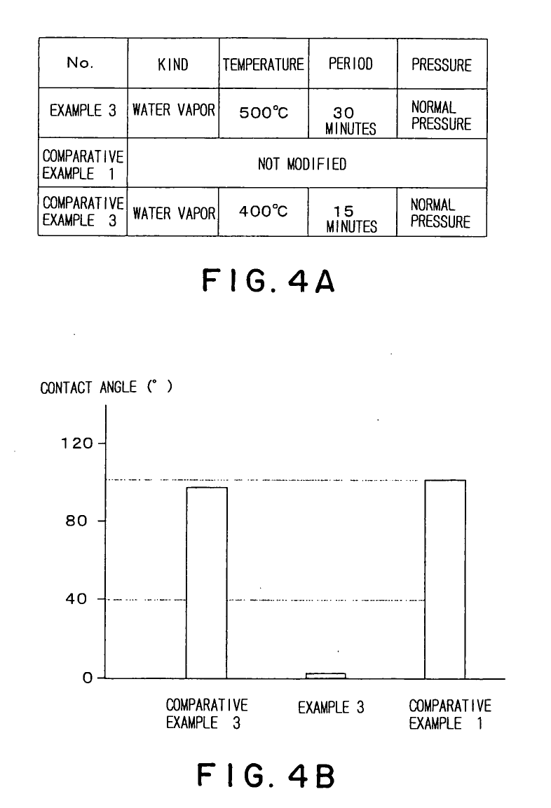

In Example 3, a surface of an interlayer insulating film was modified by water vapor, under conditions that a pressure in the reaction tube 2 was a normal pressure, a temperature in the reaction tube 2 was 500° C., and a period of supplying water vapor from the oxidizing-gas introducing tube 13 was 30 minutes. In Comparative Example 3, a surface of an interlayer insulating film was modified by water vapor, under conditions that a pressure in the reaction tube 2 was a normal pressure, a temperature in the reaction tube was 400° C., and a period of supplying water vapor from the oxidizing-gas introducing tube 13 was 15 minutes. Then, a contact angle of purified water relative to the interlayer insulating film was measured for each of the interlayer insulating films. FIG. 4A shows conditions for modifying a surface of the interlayer insulating film by water vapor. FIG. 4B shows contact angles of purified water relative to the interlayer insulating films whose surfaces have been modified.

As shown in FIGS. 4A and 4B, in the case wherein the temperature in the reaction tube 2 was 500° C. and the period for supplying water vapor from the oxidizing-gas introducing tube 13 was 30 minutes (Example 3), the contact angle of purified water relative to the interlayer insulating film was sufficiently small. Thus, it is considered that a modification of a surface of an interlayer insulating film by means of water vapor can improve adhesiveness of the interlayer insulating film, so that the interlayer insulating film can more tightly adhere to a hardmask.

On the other hand, in the case wherein the temperature in the reaction tube 2 was 400° C. and the period for supplying water vapor from the oxidizing-gas introducing tube 13 was 15 minutes (Comparative Example 3), the contact angle of purified water relative to the interlayer insulating film was more than 40°. That is, it is considered that a surface modification under these conditions cannot improve adhesiveness of an interlayer insulating film to a hardmask. Therefore, it was confirmed that, in a modification of a surface of an interlayer insulating film by means of water vapor, a temperature in the reaction tube 2 must be raised to near 500° C.

(Modification of Surface of Interlayer Insulating Film by means of (Mixed Gas of) Hydrogen and Oxygen)

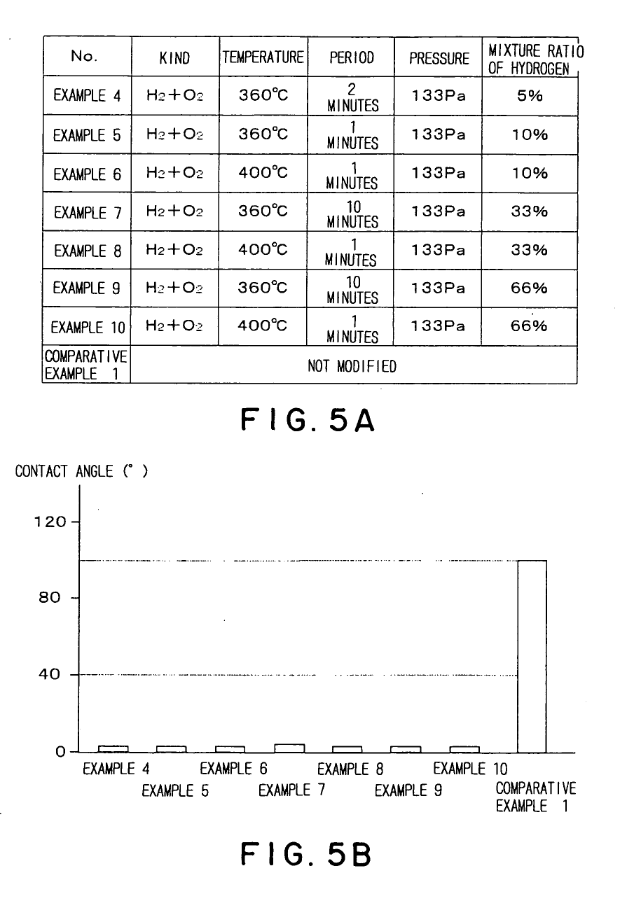

In Examples 4 to 10, a surface of an interlayer insulating film was modified by hydrogen and oxygen, under conditions that a pressure in the reaction tube was 133 Pa (1 Torr), while a temperature in the reaction tube 2, a period for supplying hydrogen and oxygen from the oxidizing-gas introducing tube 13, and a ratio of hydrogen (mixture ratio of hydrogen) were changed as shown in FIG. 5A. Then, a contact angle of purified water relative to the interlayer insulating film was measured for each of the interlayer insulating films. In this embodiment, the oxygen and the hydrogen were separately supplied into the reaction tube 2 through the separate oxidizing-gas introducing tubes 13, and then mixed in the reaction tube 2. FIG. 5A shows conditions for modifying a surface of the interlayer insulating film by means of hydrogen and oxygen. FIG. 5B shows contact angles of purified water relative to the interlayer insulating films whose surfaces have been modified.

As shown in FIGS. 5A and 5B, in the case wherein the temperature in the reaction tube 2 was in a range of from 360° C. to 400° C., the period for supplying hydrogen and oxygen from the oxidizing-gas introducing tube 13 was in a range of from 1 minute to 10 minutes, and the mixture ratio of hydrogen was in a range of from 5% to 66% (Examples 4 to 10), a contact angle of purified water relative to each of the interlayer insulating films was sufficiently small. Thus, it is considered that a modification of a surface of an interlayer insulating film by means of hydrogen and oxygen can improve adhesiveness of the interlayer insulating film, so that the interlayer insulating film can more tightly adhere to a hardmask.

In order to investigate a preferable range of temperature, a surface modification treatment was similarly carried out, with a temperature in the reaction tube 2 set at 250° C. In this case as well, a contact angle of purified water relative to the interlayer insulating film was sufficiently small. Thus, a temperature in the reaction tube 2 in the modification of a surface of an interlayer insulating film by means of hydrogen and oxygen is preferably equal to or less than 600° C., more preferably in a range of from 250° C. to 400° C.

In addition, a pressure in the reaction tube 2 when a surface of an interlayer insulating film is modified by hydrogen and oxygen is preferably in a range of from 0.3 Pa (0.003 Torr) to 101 kPa (normal pressure), more preferably in a range of from 0.3 Pa (0.003 Torr) to 0.3 kPa (3 Torr). This is because a minimum pressure of the heat treatment apparatus 1 is about 0.3 Pa, and a pressure of equal to or higher than 0.3 kPa may degrade an oxidation effect of hydrogen and oxygen.

In the modification of a surface of an interlayer insulating film by means of hydrogen and oxygen, a gas supplying period is preferably equal to or less than 60 minutes, more preferably equal to or less than 30 minutes, most preferably equal to or less than 10 minutes. A sintering period for a film of a device using the porous-MSQ is generally in a range of from 30 minutes to 60 minutes, which may be determined taking into consideration an actual productivity. A mixture ratio of hydrogen is preferably in a range of from 0.001% to 99%, more preferably in a range of from 5% to 66%. This is because addition of a slight amount of hydrogen generates radicals, which enables a surface modification treatment.

(Modification of Surface of Interlayer Insulating Film by means of Oxygen)

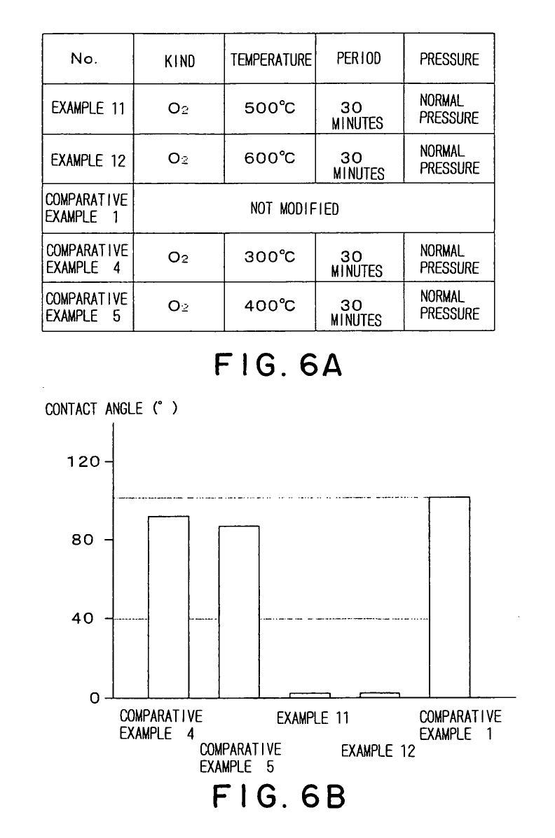

In Examples 11 and 12 and Comparative Examples 4 and 5, a surface of an interlayer insulating film was modified by oxygen, under conditions that a pressure in the reaction tube 2 was a normal pressure, a period for supplying oxygen from the oxidizing-gas introducing tube 13 was 30 minutes, while a temperature in the reaction tube 2 was set at 300° C. (Comparative Example 4), 400° C. (Comparative Example 5), 500° C. (Example 11), and 600° C. (Example 12). Then, a contact angle of purified water relative to the interlayer insulating film was measured for each of the interlayer insulating films. FIG. 6A shows conditions for modifying a surface of the interlayer insulating film by means of oxygen. FIG. 6B shows contact angles of purified water relative to the interlayer insulating films whose surfaces have been modified.

As shown in FIGS. 6A and 6B, in the case wherein the temperature in the reaction tube 2 was equal to or more than 500° C. (Examples 11 and 12), the contact angle of purified water relative to each of the interlayer insulating films was sufficiently small. Thus, it is considered that a modification of a surface of an interlayer insulating film by means of oxygen can improve adhesiveness of the interlayer insulating film, so that the interlayer insulating film can more tightly adhere to a hardmask.

On the other hand, in the case wherein the temperature in the reaction tube 2 was equal to or less than 400° C. (Comparative Examples 4 and 5), the contact angle of purified water relative to each of the interlayer insulating films was more than 40°. That is, it is considered that a surface modification under these conditions cannot improve adhesiveness of the interlayer insulating film to a hardmask. Thus, it was confirmed that, in a modification of a surface of an interlayer insulating film by means of oxygen, a temperature in the reaction tube 2 must be raised to near 500° C.

(Modification of Surface of Interlayer Insulating Film by means of Ultraviolet Rays)

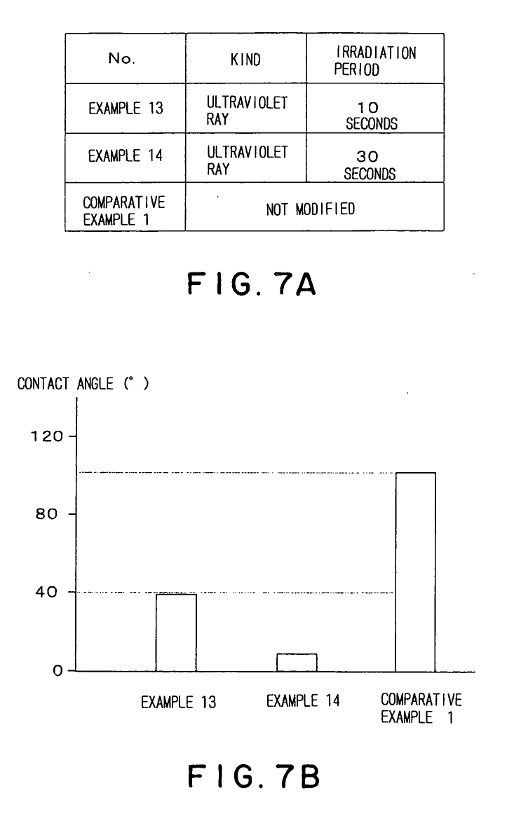

In Examples 13 and 14, a surface of an interlayer insulating film was modified by ultraviolet rays, under conditions that an ultraviolet irradiation period was set at 10 seconds (Example 13) and 30 seconds (Example 14), in an atmospheric air at a room temperature (about 25° C.). Then, a contact angle of purified water relative to the interlayer insulating film was measured for each of the interlayer insulating films. FIG. 7A shows conditions for modifying a surface of the interlayer insulating film by means of ultraviolet rays. FIG. 7B shows contact angles of purified water relative to the interlayer insulating films whose surfaces have been modified.

As shown in FIGS. 7A and 7B, in the case wherein the ultraviolet irradiation period was equal to or more than 10 seconds (Examples 13 and 14), the contact angle of purified water relative to each of the interlayer insulating films was equal to or less than 40°. In particular, in the case wherein the ultraviolet irradiation period was 30 seconds (Example 14), the contact angle of purified water relative to the interlayer insulating film was as small as equal to or less than 20°. Thus, it is considered that a modification of a surface of an interlayer insulating film by means of ultraviolet rays can improve adhesiveness of the interlayer insulating film, so that the interlayer insulating film can more tightly adhere to a hardmask. An ultraviolet irradiation period is preferably equal to or more than 10 seconds, more preferably equal to or more than 30 seconds.

It is preferable that a treatment atmosphere includes atmospheric air or oxygen, when a surface of an interlayer insulating film is modified by ultraviolet rays. This is because, in such a treatment atmosphere, oxygen radicals or ozone can be generated by an ultraviolet irradiation. In the modification of a surface of an interlayer insulating film by means of ultraviolet rays, a temperature in the reaction tube 2 is preferably equal to or less than 600° C., more preferably equal to or less than 400° C. In the modification of a surface of an interlayer insulating film by means of ultraviolet rays, a pressure in the reaction tube 2 is preferably in a range of from 0.3 Pa (0.003 Torr) to 101 kPa (normal pressure).

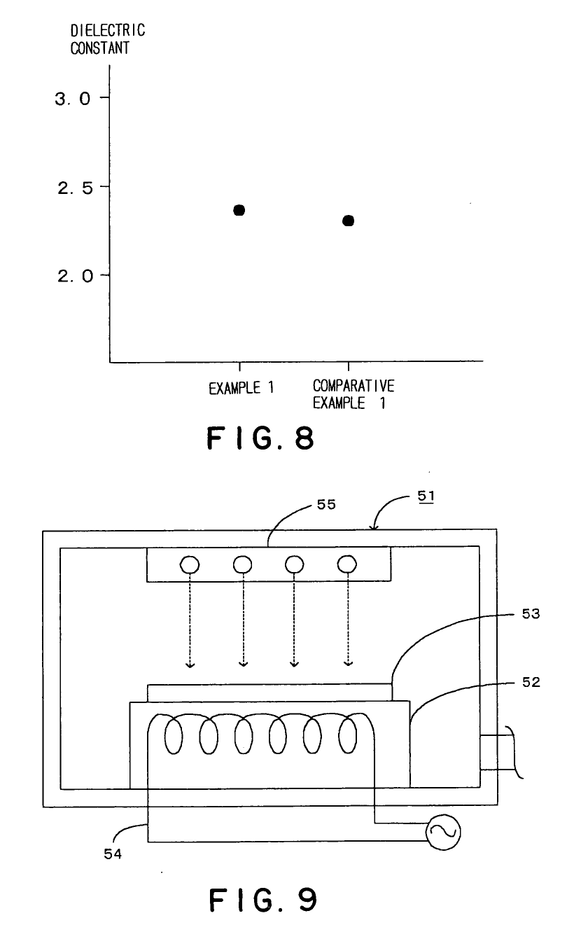

In order to examine whether a film property of an interlayer insulating film is deteriorated by a surface modification treatment according to the present invention, a dielectric constant of an interlayer insulating film whose surface had been modified was measured. FIG. 8 shows measured results of a dielectric constant of an interlayer insulating film whose surface was modified as shown in Example 1, and a dielectric constant of an interlayer insulating film whose surface was not modified as shown in Comparative Example 1. As shown in FIG. 8, there is little difference between the dielectric constant of the interlayer insulating film whose surface was modified as shown in Example 1 and the dielectric constant of the interlayer insulating film whose surface was not modified. Thus, it was verified that a modification of a surface of an interlayer insulating film according to the present invention can improve adhesiveness of the interlayer insulating film, while a dielectric constant thereof is maintained. Upon observation of the modified surface of the interlayer insulating film, no serious roughness was found in the surface of the interlayer insulating film. Therefore, it was verified that a modification of a surface of an interlayer insulating film according to the present invention can improve adhesiveness of the interlayer insulating film, while deterioration of a film property of the interlayer insulating film is prevented.

As explained above, according to the respective embodiments of the present invention, adhesiveness of an interlayer insulating film can be improved while maintaining a dielectric constant thereof, by supplying an oxidizing gas into the reaction vessel 2 which has been heated at a predetermined temperature, or by emitting ultraviolet rays onto the interlayer insulating film. In addition, the adhesiveness of an interlayer insulating film can be improved without deterioration of a property thereof.

Not limited to the above embodiments, various changes and modifications can be made in the present invention.

In the foregoing embodiments, the semiconductor wafer 10 is spin-coated with a coating solution including polysiloxane having an organic functional group to form a coating film, and the coating film is then sintered to form an interlayer insulating film on the semiconductor wafer. However, the present invention is not limited thereto, and it can be applied to various kinds of interlayer insulating films. Note that, however, the present invention is particularly effective when applied to an interlayer insulating film of a low dielectric constant, since the interlayer insulating film of a low dielectric constant tends to be separated from another film formed thereon. Not limited to the porous-MSQ, an interlayer insulating film of a low dielectric constant includes various other kinds of interlayer insulating films of a low dielectric constant.

In the foregoing embodiments, the semiconductor wafer 10 is spin-coated with a coating solution including polysiloxane having an organic functional group to form a coating film, and the coating film is then sintered to form an interlayer insulating film on the semiconductor wafer 10. Herein, after the step of sintering the coating film, it is possible to consecutively perform a step of modifying a surface of the interlayer insulating film by using the batch-type vertical heat treatment apparatus 1.

In the foregoing embodiments, although the batch-type heat treatment apparatus 1 including the reaction tube 2 of a double tube structure formed of the inner tube 3 and the outer tube 4 is used, the present invention is not limited thereto. For example, the present invention can be applied to a batch-type vertical heat treatment apparatus of a single tube structure, which is not provided with the inner tube 3.

The apparatus for modifying a surface of an interlayer insulating film according to the present invention is not limited to a batch-type heat treatment apparatus. For example, the apparatus may be a sheet-fed type heat treatment apparatus as shown in FIG. 9. FIG. 9 shows a heat treatment apparatus 51 for modifying a surface of an interlayer insulating film by means of an ultraviolet irradiation. In the heat treatment apparatus 51 shown in FIG. 9, a semiconductor wafer 53 having an interlayer insulating film formed thereon is placed on a table 52. The semiconductor wafer 53 is maintained at a predetermined temperature by a heater 54 disposed in the table 52. An ultraviolet emitting part 55 having a plurality of ultraviolet lamps is disposed at an upper part of the heat treatment apparatus 51. Ultraviolet rays are emitted from the ultraviolet emitting part 55 onto the semiconductor wafer 53. A surface of the interlayer insulating film formed on the semiconductor wafer 53 is modified by the ultraviolet rays, such that the surface has an improved adhesiveness, with a dielectric constant thereof being maintained.

In the above embodiments, ozone, water vapor, oxygen, and hydrogen and oxygen are used as an oxidizing gas. However, not limited thereto, an oxidizing gas may be any gas, provided that it can increase a polar component energy in a surface energy of an interlayer insulating film.

1. A method for modifying a surface of an interlayer insulating film that is formed by applying a coating solution on a substrate to form a coating film, and sintering the coating film at a predetermined temperature, the method comprising the steps of:
heating an inside of a reaction chamber that contains a substrate to a predetermined temperature; and
modifying a surface of the interlayer insulating film by supplying an oxidizing gas into the reaction chamber.

2. The method for modifying a surface of an interlayer insulating film according to claim 1, wherein
the oxidizing gas is any one of ozone, water vapor, oxygen, or a mixed gas of hydrogen and oxygen.

3. The method for modifying a surface of an interlayer insulating film according to claim 2, wherein
the predetermined temperature is in a range of from 250° C. to 600° C.; and
the oxidizing gas is ozone.

4. The method for modifying a surface of an interlayer insulating film according to claim 2, wherein
the predetermined temperature is in a range of from 250° C. to 600° C.; and
the oxidizing gas is a mixed gas of hydrogen and oxygen.

5. The method for modifying a surface of an interlayer insulating film according to any one of claims 1 to 4, wherein
during the step of modifying a surface of the interlayer insulating film, the surface of the interlayer insulating film is modified such that a surface energy of the interlayer insulating film is at least 80 mN/m.

6. The method for modifying a surface of an interlayer insulating film according to any one of claims 1 to 4, wherein
during the step of modifying a surface of the interlayer insulating film, the surface of the interlayer insulating film is modified such that a surface contact angle of water on the surface of the interlayer insulating film is less than 40°.

7. The method for modifying a surface of an interlayer insulating film according to any one of claims 1 to 4, wherein
the interlayer insulating film is an interlayer insulating film of a low dielectric constant.

8. The method for modifying a surface of an interlayer insulating film according to claim 7, wherein
the interlayer insulating film of a low dielectric constant is formed of a coating solution including polysiloxane having an organic functional group.

9. An apparatus for modifying a surface of an interlayer insulating film that is formed by applying a coating solution on a substrate to form a coating film, and sintering the coating film at a predetermined temperature, the apparatus comprising:
a reaction chamber that contains the substrate;
a heating unit that heats an inside of the reaction chamber to a predetermined temperature;
an oxidizing gas supplying unit that supplies an oxidizing gas into the reaction chamber; and
a controller that controls the heating unit and the oxidizing gas supplying unit.

10. The apparatus for modifying a surface of an interlayer insulating film according to claim 9, wherein
the oxidizing gas is any one of ozone, water vapor, oxygen, or a mixed gas of hydrogen and oxygen.

11. The apparatus for modifying a surface of an interlayer insulating film according to claim 10, wherein
the predetermined temperature is in a range of from 250° C. to 600° C.; and
the oxidizing gas is ozone.

12. The apparatus for modifying a surface of an interlayer insulating film according to claim 10, wherein
the predetermined temperature is in a range of from 250° C. to 600° C.; and
the oxidizing gas is a mixed gas of hydrogen and oxygen.

13. The apparatus for modifying a surface of an interlayer insulating film according to any one of claims 9 to 12, wherein
the controller controls the heating unit and the oxidizing gas supplying unit such that a surface energy of the interlayer insulating film is at least 80 mN/m.

14. The apparatus for modifying a surface of an interlayer insulating film according to any one of claims 9 to 12, wherein
the controller controls the heating unit and the oxidizing gas supplying unit such that a surface contact angle of water on the surface of the interlayer insulating film is less than 40°.

15. The apparatus for modifying a surface of an interlayer insulating film according to any one of claims 9 to 12, wherein
the interlayer insulating film is an interlayer insulating film of a low dielectric constant.

16. The apparatus for modifying a surface of an interlayer insulating film according to claim 15, wherein
the interlayer insulating film of a low dielectric constant is formed of a coating solution including polysiloxane having an organic functional group.
